(19) United States
(12) Patent Application Publication
(10) Pub. No.: US 2012/0200752 A1
(43) Pub. Date: Aug. 9, 2012

(54) SOLID-STATE IMAGE PICKUP DEVICE

(75) Inventor: Yoshiyuki MATSUNAGA, Kyoto (JP)

(73) Assignee: PANASONIC CORPORATION, Osaka (JP)

(21) Appl. No.: 13/449,946

(22) Filed: Apr. 18, 2012

Related U.S. Application Data
(63) Continuation of application No. PCT/JP2010/004494, filed on Jul. 12, 2010.

(30) Foreign Application Priority Data
Nov. 12, 2009 (JP) 2009-259011

(51) Int. Cl. H04N 5/335; H01L 27/146

(52) U.S. Cl. 348/300; 250/208.1; 348/E05.091

(57) ABSTRACT

A solid-state image pickup device includes a plurality of pixels arranged in rows and columns on a semiconductor substrate. A photoelectric converter of each pixel includes a photoelectric conversion film between a pixel electrode and a transparent electrode. An amplifier transistor has a gate connected to the pixel electrode, and a reset transistor has a source connected to the pixel electrode. The solid-state image pickup device performs: hard reset operation in which a first reset voltage is applied to the drain of the reset transistor, and then the reset transistor is turned on; and soft reset operation in which a second reset voltage which has a higher level than the first reset voltage is applied to the drain of the reset transistor, and then a pulse in a negative direction is applied to the source of the reset transistor via a capacitor.

### CROSS-REFERENCE TO RELATED APPLICATION

This is a continuation of PCT International Application PCT/JP2010/004494 filed on Jul. 12, 2010, which claims priority to Japanese Patent Application No. 2009-259011 filed on Nov. 12, 2009. The disclosures of these applications including the specifications, the drawings, and the claims are hereby incorporated by reference in their entirety.

### BACKGROUND

The present disclosure relates to solid-state image pickup devices, and specifically to stacked solid-state image pickup devices.

In recent years, pixels of solid-state image pickup devices which include a photodiode provided in a semiconductor substrate made of crystalline silicon, and use a charge coupled device (CCD) or a metal oxide semiconductor (MOS) as a scan circuit have been rapidly miniaturized. The pixel size, which was 3 μm about 2000, has been reduced to 2 μm in 2007. In 2010, solid-state image pickup devices having a pixel size of 1.4 μm will be put to practical use. If the pixel size is reduced at this rate, it is expected that the pixel size can be reduced to 1 μm or smaller in the next few years.

However, the inventor of the present application was found that a first problem which arises because the optical absorption coefficient of crystalline silicon is small, and a second problem related to the amount of processed signals have to be solved in order to reduce the pixel size to 1 μm or smaller. The first problem will be described in detail. The optical absorption coefficient of crystalline silicon depends on the wavelength of light. Crystalline silicon having a thickness of about 3.5 μm is required in order to almost perfectly absorb green light near a 550 μm wavelength determining the sensitivity of solid-state image pickup devices and to perform photoelectric conversion on the absorbed light. Thus, the depth of a photodiode formed in a semiconductor substrate has to be about 3.5 μm. If the two-dimensional pixel size is 1 μm, forming a photodiode having a depth of about 3.5 μm is very difficult. Even if a photodiode having a depth of about 3.5 μm can be formed, a problem that obliquely incident light enters a photodiode of an adjacent pixel is more likely to occur. When the obliquely incident light enters the photodiode of the adjacent pixel, a color mixture (crosstalk) is present, which is a major problem in color solid-state image pickup elements. When a photodiode is formed to have a depth less than about 3.5 μm in order to avoid the color mixture, the green light absorption efficiency is reduced, so that the sensitivity of an image sensor is reduced. In miniaturizing pixels, the pixel size is reduced, so that the sensitivity of each pixel is reduced. A reduction in light absorption efficiency in addition to the reduction in the sensitivity of each pixel is critical.

The second problem will be described in detail. The amount of processed signals depends on the saturated charge amount of a buried photodiode having a photodiode structure used in general solid-state image pickup devices. The buried photodiode has the advantage that the buried photodiode can almost completely transfer signal charge stored therein to an adjacent charge detection section (complete transfer). Thus, almost no noise related to charge transfer is generated, so that buried photodiodes are widely used in solid-state image pickup devices. However, achieving the complete transfer does not allow an increase in capacity per unit area of a photodiode. Thus, miniaturizing pixels causes a problem that saturated charge decreases. Compact digital cameras require a saturated electron number of 10000 electrons per pixel, but when the pixel size is about 1.4 μm, the saturated electron number is limited to about 5000 electrons. Currently, pictures are formed by a noise reducing process, or the like by using a digital signal process technique to counter the reduction in saturated electron number, but obtaining natural reproduction pictures is difficult. Moreover, it is said that high-grade single-lens reflex cameras require a saturated electron number of about 30000 electrons per pixel.

Note that in MOS type image sensors using a crystalline silicon substrate, a structure is considered in which light does not enter a front side on which pixel circuits are formed by shaving the substrate, but enters a back side. However, with this structure, it is possible only to avoid that incident light is blocked by interconnects or the like included in the pixel circuits, but it is possible to solve neither the first problem nor the second problem.

Examples of an expected technique to solve the two problems include a stacked solid-state image pickup device (for example, see Japanese Patent Publication No. S55-120182). The stacked solid-state image pickup device has a configuration in which a photoelectric conversion film is formed on an insulating film on a semiconductor substrate on which pixel circuits are formed. Thus, for the photoelectric conversion film, a material such as amorphous silicon having a high optical absorption coefficient can be used. For example, in the case of amorphous silicon, green light having a 550 nm wavelength can be almost completely absorbed when the amorphous silicon has a thickness of about 0.4 nm.

Moreover, no buried photodiode is used, so that it is possible to increase the capacity of the photoelectric converter, and thus the saturated charges can be increased. Furthermore, complete transfer of the charges is not performed, so that adding additional capacitor can also be promoted. Thus, a sufficiently large capacity can be obtained even in miniaturized pixels, which can solve the second problem. A configuration such as stack cells in a dynamic random access memory is also possible.

### SUMMARY

However, in conventional stacked solid-state image pickup devices, the level of random noise is high, and a dark current is large. In the conventional stacked solid-state image pickup devices, noise is generated in resetting signal charge. In a state in which noise is generated, next signal charge is added, so that signal charge on which reset noise is superimposed is read. Thus, the level of the random noise increases.

Moreover, in the conventional stacked solid-state image pickup devices, a photoelectric conversion film is formed spaced apart from a surface of the semiconductor substrate, and thus the photoelectric conversion film has to be electrically connected to the semiconductor surface. Thus, the value of a dark current increases, which was not a problem in buried photodiodes.

There is a known technique of combining strong inversion operation and weak inversion operation of a reset transistor with each other in resetting a signal, thereby reducing noise to 1/√2. However, as the solid-state image pickup devices are miniaturized, it becomes difficult to reduce noise by such a method. Moreover, a method for reducing the random noise by feedback in resetting a signal has been proposed. However, a rolling reset is generally used, where in the rolling reset, performing feedback on only one column of pixels arranged in rows and columns to reduce noise is repeated. A global reset in which pixels arranged in rows and columns are simultaneously reset while reducing noise is also possible, but the global reset consumes a lot of power, and thus the global reset is not realistic. As to specific values, a current of bout 5 μA per pixel has to be fed for resetting while reducing noise. When the rolling reset is performed on a 1000×1000 pixel solid-state image pickup device, a current is fed simultaneously to 1000 pixels in one column, and thus a current of about 5 mA is required. It is sufficiently possible to feed this level of current. However, in order to perform the global reset simultaneously on all the pixels of the 1000×1000 pixel solid-state image pickup device, a current of about 5 A is required, and this is not realistic.

However, in order to use solid-state image pickup devices in compact digital cameras, the global reset is essential. In single-lens reflex digital cameras, a mechanical shutter is opened to start introduction of incident light, and the mechanical shutter is closed to end the introduction of the incident light. Thus, the global reset is not essential. In contrast, in compact digital cameras, an electronic shutter, that is, a global reset is performed to start introduction of incident light, and the mechanical shutter is closed to end the introduction of the incident light. Thus, in the compact digital cameras, the global reset is essential.

It is an objective of the present disclosure to provide a stacked solid-state image pickup device in which the above-discussed problems are solved, a global reset can be performed, the level of noise is low, and a dark current is small.

To achieve the above objective, a solid-state image pickup device of the present disclosure is configured such that a hard reset is combined with a soft reset, and in the soft reset, a potential of a reset transistor is reduced to be lower than a ground potential.

Specifically, a first solid-state image pickup device includes: a semiconductor substrate; a plurality of pixels arranged in rows and columns on the semiconductor substrate; and a vertical signal line provided to each column, wherein each pixel includes a reset transistor, an address transistor, an amplifier transistor, and a photoelectric converter which are formed on the semiconductor substrate, the photoelectric converter includes a photoelectric conversion film formed over the semiconductor substrate, a pixel electrode formed on a surface of the photoelectric conversion film facing the substrate, and a transparent electrode formed on a surface of the photoelectric conversion film opposite to the pixel electrode, a gate of the amplifier transistor is connected to the pixel electrode, a source of the reset transistor is connected to the pixel electrode, and the solid-state image pickup device performs hard reset operation in which a first reset voltage is applied to a drain of the reset transistor, and then the reset transistor is turned on, and soft reset operation in which a second reset voltage at a higher level than the first reset voltage is applied to the drain of the reset transistor, and then a pulse in a negative direction is applied to the source of the reset transistor via a capacitor.

The first solid-state image pickup device performs the soft reset operation in which a high second reset voltage at a level higher than a level of the first reset voltage is applied to the drain of the reset transistor, and then a pulse in a negative direction is applied to the source of the reset transistor via a capacitor. Thus, even when the pixels are miniaturized, noise can be reduced to 1/√2 which is a level in the case of only a hard reset.

The first solid-state image pickup device may have a configuration in which the first reset voltage is 0 V or a positive voltage near 0 V, and the soft reset operation is performed after the reset transistor is turned off. With this configuration, the source of the reset transistor is a minus voltage equal to 0 V or lower, and electrons in the source are released into the semiconductor substrate.

In the first solid-state image pickup device, the capacitor may be formed by using the photoelectric conversion film as a capacitor film.

The first solid-state image pickup device may further include a reset drain control line provided to each column and connected to the drains of the reset transistors; and differential amplifiers each having input terminals one of which is connected to the reset drain control line and an output terminal connected to the reset drain control line via a switch. With this configuration, it is possible to easily switch between global reset operation and rolling reset operation.

A second solid-state image pickup device includes a semiconductor substrate; a plurality of pixels arranged in rows and columns on the semiconductor substrate; a vertical signal line provided to each column; and vertical signal line fixing switches each configured to fix a potential of the vertical signal line, wherein each pixel includes a first feedback transistor, a second feedback transistor, an address transistor, an amplifier transistor, a photoelectric converter, a feedback capacitor, and a zero-bias capacitor which are formed on the semiconductor substrate, the photoelectric converter includes a photoelectric conversion film formed over the semiconductor substrate, a pixel electrode formed on a surface of the photoelectric conversion film facing the substrate, and a transparent electrode formed on a surface of the photoelectric conversion film opposite to the pixel electrode, the amplifier transistor has a gate connected to the pixel electrode, a source connected to the vertical signal line, and a drain connected to a source of the address transistor, the second feedback transistor has a source connected to the pixel electrode, and a drain connected to a source of the first feedback transistor, the first feedback transistor has a drain connected to the source of the address transistor, the zero-bias capacitor is connected to the gate of the amplifier transistor, and the feedback capacitor is connected between the source and the drain of the second feedback transistor.

The second solid-state image pickup device includes a first feedback transistor and a second feedback transistor. Thus, a high level of noise generated in first feedback operation performed with the first feedback transistor and the second feedback transistor being in an on state can be converted to a low level of noise resulting from the feedback capacitor by second feedback operation performed by the second feedback transistor.

A third solid-state image pickup device includes a semiconductor substrate; a plurality of pixels arranged in rows and columns on the semiconductor substrate; a vertical signal line provided to each column; and vertical signal line fixing switches each configured to fix a potential of the vertical signal line, wherein each pixel includes a first feedback transistor, a second feedback transistor, an address transistor, an amplifier transistor, a photoelectric converter, a feedback capacitor, a zero-bias capacitor which are formed on the semiconductor substrate, the photoelectric converter includes a photoelectric conversion film formed over the semiconductor substrate, a pixel electrode formed on a surface of the photoelectric conversion film facing the substrate, and a transparent electrode formed on a surface of the photoelectric conversion film opposite to the pixel electrode, the amplifier transistor has a gate connected to the pixel electrode, a source connected to the vertical signal line, and a drain connected to a source of the address transistor, the second feedback transistor has a source connected to the pixel electrode, and a drain connected to the source of the address transistor, the first feedback transistor has a source connected to the pixel electrode via the feedback capacitor, and a drain connected to the source of the address transistor, and the zero-bias capacitor is connected to the gate of the amplifier transistor.

The third solid-state image pickup device includes a first feedback transistor and a second feedback transistor. Thus, a high level of noise generated in first feedback operation performed with the first feedback transistor and the second feedback transistor being in an on state can be converted to a low level of noise resulting from the feedback capacitor by second feedback operation performed by the second feedback transistor.

The second and third solid-state image pickup devices each may be configured to perform first feedback operation in which the vertical signal line fixing switch is turned on to fix a voltage of the vertical signal line, a high-level voltage is applied to the zero-bias capacitor, the first feedback transistor and the second feedback transistor are turned on, and the address transistor is turned on, and then the address transistor is brought back into an off state; second feedback operation in which the vertical signal line fixing switch is turned on to fix the voltage of the vertical signal line, the high-level voltage is applied to the zero-bias capacitor, the first feedback transistor is turned on, the second feedback transistor is turned off, and the address transistor is turned on, and then the address transistor is brought back into the off state; and storage operation in which a low-level voltage is applied to the zero-bias capacitor, and the first feedback transistor and the second feedback transistor are turned off.

In the second and third solid-state image pickup devices, a gate length of the amplifier transistor may be greater than a gate length of each of the first feedback transistor, the second feedback transistor, and the address transistor.

A fourth solid-state image pickup device includes a semiconductor substrate; a plurality of pixels arranged in rows and columns on the semiconductor substrate; a vertical signal line provided to each column; a reset drain control line provided to each column; vertical signal line fixing switches each configured to fix a potential of the vertical signal line; and differential amplifiers each having input terminals one of which is connected to the vertical signal line and an output terminal connected to the reset drain control line via a switch, wherein each pixel includes a feedback transistor, a reset transistor, an address transistor, an amplifier transistor, a photoelectric converter, a feedback capacitor, and a zero-bias capacitor which are formed on the semiconductor substrate, the photoelectric converter includes a photoelectric conversion film formed over the semiconductor substrate, a pixel electrode formed on a surface of the photoelectric conversion film facing the substrate, and a transparent electrode formed on a surface of the photoelectric conversion film opposite to the pixel electrode, the amplifier transistor has a gate connected to the pixel electrode, a source connected to the vertical signal line, and a drain connected to a source of the address transistor, the feedback transistor has a source connected to the pixel electrode via the feedback capacitor, and a drain connected to the source of the address transistor, the reset transistor has a source connected to the pixel electrode, and a drain connected to the reset drain control line, and the zero-bias capacitor is connected to the gate of the amplifier transistor.

The fourth solid-state image pickup device includes the reset transistor and the feedback transistor. Thus, a high level of noise generated in reset operation can be converted to a low level of noise resulting from the feedback capacitor by feedback operation. Moreover, rolling reset operation can be performed.

The fourth solid-state image pickup device may be configured to perform reset operation in which a reset voltage is applied to the reset drain control line to bring the reset transistor into an on state; feedback operation in which the vertical signal line fixing switch is turned on to fix a voltage of the vertical signal line, a high-level voltage is applied to the zero-bias capacitor, the feedback transistor is turned on, and the address transistor is turned on, and then the address transistor is brought back into an off state; and storage operation in which a low-level voltage is applied to the zero-bias capacitor, and the feedback transistor is turned off.

In the fourth solid-state image pickup device, a gate length of the amplifier transistor is preferably greater than a gate length of each of the feedback transistor, the reset transistor, and the address transistor.

A fifth solid-state image pickup device includes: a semiconductor substrate; a plurality of pixels arranged in rows and columns on the semiconductor substrate; a vertical signal line provided to each column; and feedback units, wherein each pixel includes a reset transistor having a function of resetting a signal charge, an address transistor, an amplifier transistor, and a photoelectric converter which are formed on the semiconductor substrate, the photoelectric converter includes a photoelectric conversion film formed over the semiconductor substrate, a pixel electrode formed on a surface of the photoelectric conversion film facing the substrate, and a transparent electrode formed on a surface of the photoelectric conversion film opposite to the pixel electrode, the amplifier transistor has a gate connected to the pixel electrode, the reset transistor has a source connected to the pixel electrode, each feedback unit is connected to a drain of the reset transistor and is configured to feed back a voltage output inverted with respect to an input of the amplifier transistor.

In the fifth solid-state image pickup device, a voltage output inverted with respect to an input of the amplifier transistor is fed back to the drain of the reset transistor. Thus, noise can be reduced by negative feedback.

In the fifth solid-state image pickup device, each feedback unit may be provided to an associated one of the pixels, or each feedback unit may be provided to an associated one of the columns in correspondence with the vertical signal line.

In the fifth solid-state image pickup device, an input of the amplifier transistor in operation of the feedback unit may be a positive voltage near 0 V at a direct current level.

The fifth solid-state image pickup device may further include a zero-bias capacitor which is capacitively coupled to the pixel electrode, and sets the voltage of the pixel electrode to a positive voltage in a vicinity of 0 V.

The first to fifth solid-state image pickup devices preferably have a function of switching between a global reset and a rolling reset.

A camera system according to the present disclosure includes the solid-state image pickup device of the present disclosure.

With the solid-state image pickup device according to the present disclosure, it is possible to obtain a stacked solid-state image pickup device which is capable of performing a global reset, has reduced noise, and has a reduced dark current.

### BRIEF DESCRIPTION OF THE DRAWINGS

FIG. 1 is a circuit diagram illustrating a solid-state image pickup device according to a first embodiment.

FIG. 2 is a cross-sectional view illustrating one pixel of the solid-state image pickup device according to the first embodiment.

FIG. 3 is a view illustrating a state of a potential at the position taken along the line III-III of FIG. 2.

FIG. 4A is a circuit diagram illustrating a circuit configuration in the periphery of a general reset transistor. FIGS. 4B-4F are views illustrating states of potentials in the periphery of the reset transistor in general reset operation.

FIG. 5 is a view illustrating the voltage-current characteristic of a transistor in a weak-inversion state.

FIG. 6A is a circuit diagram illustrating a circuit configuration in the periphery of a reset transistor according to the first embodiment. FIGS. 6B-6G are views illustrating states of potentials in the periphery of the reset transistor in reset operation according to the first embodiment.

FIG. 7 is a cross-sectional view illustrating bipolar operation of the reset transistor of the first embodiment.

FIG. 8 is a view illustrating a configuration of a camera according to the first embodiment.

FIG. 9 is a timing diagram illustrating driving timing of the solid-state image pickup device according to the first embodiment.

FIG. 10 is a timing diagram illustrating driving timing of a variation of the solid-state image pickup device according to the first embodiment.

FIG. 11 is a circuit diagram illustrating a solid-state image pickup device according to a variation of the first embodiment.

FIG. 12 is a circuit diagram illustrating a solid-state image pickup device according to a second embodiment.

FIGS. 13A, 13B illustrate a state of a transistor in weak-inversion operation, where FIG. 13A is a circuit diagram, and FIG. 13B is a view illustrating states of potentials.

FIGS. 14A, 14B illustrate a state of a transistor in weak-inversion feedback operation, where FIG. 14A is a circuit diagram, and FIG. 14B is a view illustrating states of potentials.

FIGS. 15A, 15B illustrate a state of a transistor in weak-inversion feedback operation with a capacitor being inserted, where FIG. 15B is a circuit diagram, and FIG. 15B is a view illustrating states of potentials.

FIG. 16 is a timing diagram illustrating driving timing of the solid-state image pickup device according to the second embodiment.

FIG. 17 is a circuit diagram illustrating one pixel of a solid-state image pickup device according to a variation of the second embodiment.

FIG. 18 is a circuit diagram illustrating a solid-state image pickup device of a third embodiment.

### DETAILED DESCRIPTION

### First Embodiment

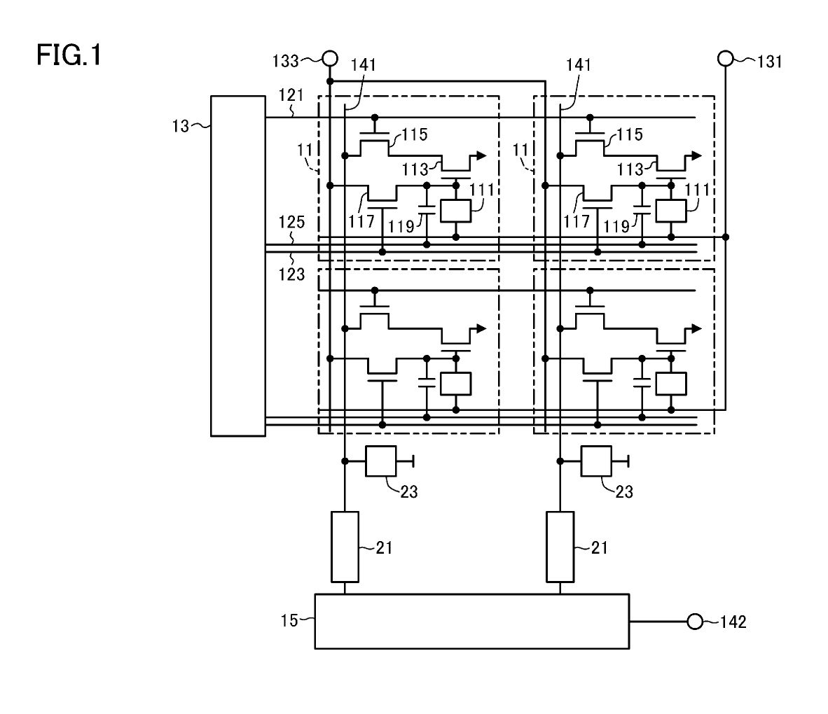

FIG. 1 illustrates a circuit configuration of a solid-state image pickup device according to the present embodiment. As illustrated in FIG. 1, a plurality of pixels 11 arranged in rows and columns, a vertical scan section 13 configured to feed various timing signals to the pixels 11, and a horizontal signal read section 15 configured to read signals from the pixels 11 to a sequential horizontal output 142 are provided. In FIG. 1, the pixels 11 only in two rows and two columns are illustrated, but the number of rows and columns may be set arbitrarily.

Each pixel 11 includes a photoelectric converter 111, an amplifier transistor 113 whose gate is connected to the photoelectric converter 111, a reset transistor 117 whose source is connected to the photoelectric converter 111, and an address transistor 115 whose drain is connected to the source of the amplifier transistor 113. The photoelectric converter 111 is connected between (i) the gate of the amplifier transistor 113 and the source of the reset transistor 117 and (ii) a photoelectric converter control line 131. The source of the address transistor 115 is connected to a corresponding vertical signal line 141. The gate of the address transistor 115 is connected to the vertical scan section 13 via an address control line 121. The drain of the reset transistor 117 is connected to a reset drain control line 133, and the gate of the reset transistor 117 is connected to the vertical scan section 13 via a reset control line 123. Between the source of the reset transistor 117 and a bipolar operation control line 125, a reset control capacitor 119 is connected. The bipolar operation control line 125 is connected to the vertical scan section 13.

The vertical signal line 141 is provided to each column, and is connected to the horizontal signal read section 15 via a column signal processing section 21. The column signal processing section 21 performs noise reduction signal processing such as correlated double sampling, analog to digital conversion, etc. Moreover, a load section 23 is connected to the vertical signal line 141. The address control line 121, the reset control line 123, and the bipolar operation control line 125 are provided to each row. The photoelectric converter control line 131 and the reset drain control line 133 are shared among all the pixels.

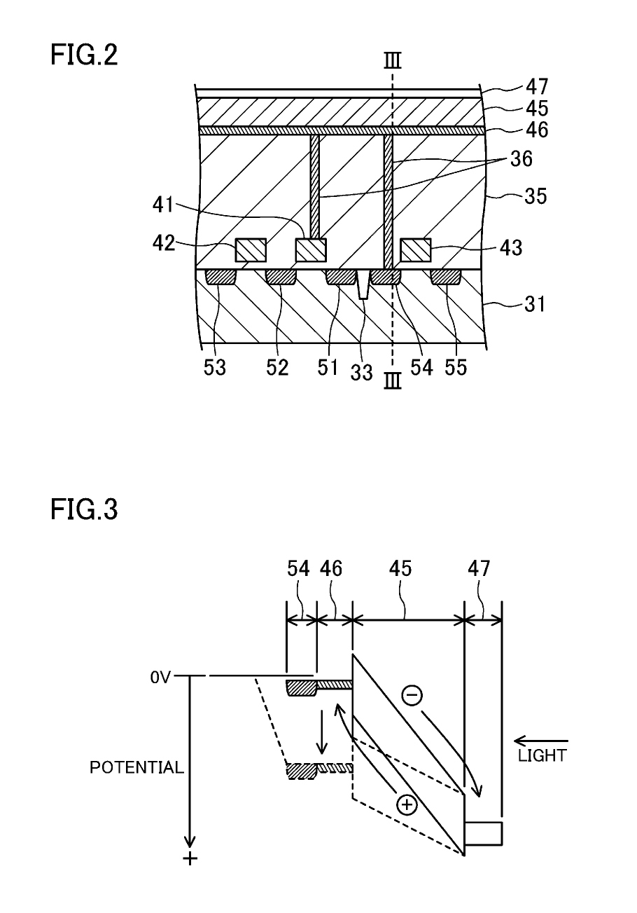

The solid-state image pickup device of the present embodiment is a stacked solid-state image pickup device. Each pixel 11 has a configuration described below. FIG. 2 illustrates a cross-sectional configuration of the pixel 11 of the solid-state image pickup device of the present embodiment. As illustrated in FIG. 2, on a semiconductor substrate 31 made of silicon, an amplifier transistor, an address transistor, and a reset transistor are formed. The amplifier transistor includes a gate electrode 41, a diffusion layer 51 serving as the drain, and a diffusion layer 52 serving as the source. The address transistor 115 includes a gate electrode 42, a diffusion layer 52 serving as the drain, and a diffusion layer 53 serving as the source. The source of the amplifier transistor and the drain of the address transistor form a common diffusion layer. The reset transistor includes a gate electrode 43, a diffusion layer 54 serving as the source, and a diffusion layer 55 serving as the drain. The diffusion layer 51 is isolated from the diffusion layer 54 by a device isolation region 33.

On the semiconductor substrate 31, an insulating film 35 is formed to cover the transistors. On the insulating film 35, the photoelectric converter 111 is formed. The photoelectric converter 111 includes a photoelectric conversion film 45 made of, for example, amorphous silicon, a pixel electrode 46 formed on a lower surface of the photoelectric conversion film 45, and a transparent electrode 47 formed on an upper surface of the photoelectric conversion film 45. The pixel electrode 46 is connected to the gate electrode 41 of the amplifier transistor 113 and the diffusion layer 54 serving as the source of the reset transistor 117 via contacts 36. The diffusion layer 54 connected to the pixel electrode 46 serves as a storage diode.

Next, operation of the solid-state image pickup device of the present embodiment will be described. Note that in the following description, it is provided that the amplifier transistor 113, the address transistor 115, and the reset transistor 117 are n-channel transistors formed on a p-type semiconductor substrate, and including n-type diffusion layers. Thus, the term “high-level voltage” means a voltage having a higher potential than a reference voltage, and the term “low-level voltage” or “low-level signal” means a voltage or a signal having a lower potential than the reference voltage. Note that the amplifier transistor 113, the address transistor 115, and the reset transistor 117 may be p-channel transistors. In this case, positive and negative polarities of the voltage in the following description are inverted. Thus, the term “high-level voltage” or “high-level signal” means a voltage or a signal having a lower potential than the reference voltage, and the term “low-level voltage” or “low-level signal” means a voltage or a signal having a higher potential than the reference voltage.

FIG. 3 illustrates the potential along the line III-III of FIG. 2. First, in a state in which no signal is provided, the potential of the diffusion layer 54 serving as the storage diode is substantially 0 V, and is slightly reverse-biased. When the reverse bias is about 25 mV generated by heat noise, part of charge in the storage diode may be discharged into the substrate. For this reason, the reverse bias applied during a period of storing signal charge is preferably about 0.1 V or higher. When the potential of the storage diode is set to about 0 V, a reverse leakage current (dark current) flowing between the storage diode and the semiconductor substrate 31 can be reduced. In contrast, a positive voltage is applied to the transparent electrode 47. Light entering an upper portion of the transparent electrode 47 passes through the transparent electrode 47, and enters the photoelectric conversion film 45, in which the light is converted to an electron-hole pair. The electron of the converted electron-hole pair is transported to the transparent electrode 47, and flows to a power supply (not shown) connected to the transparent electrode 47. The hole is transported to the diffusion layer 54, and is stored in the diffusion layer 54. For this reason, the potential of the diffusion layer 54 increases in the positive direction, and a voltage is applied between the diffusion layer 54 and the semiconductor substrate 31. Thus, the reverse leakage current (dark current) flows between the diffusion layer 54 and the semiconductor substrate 31, thereby generating noise. However, in a state in which a signal is provided, noise is insignificant, and thus causes no problem.

The voltage increased in the positive direction by the hole stored in the diffusion layer 54 is transferred to the gate electrode 41 of the amplifier transistor 113, and the signal charge amplified by the amplifier transistor 113 is output to the vertical signal line 141 via the address transistor 115.

Next, the signal charge stored in the diffusion layer 54 is reset. In resetting the signal charge, a high level of noise is generated. First, reset operation by a normal combination of a hard reset and a soft reset will be described.

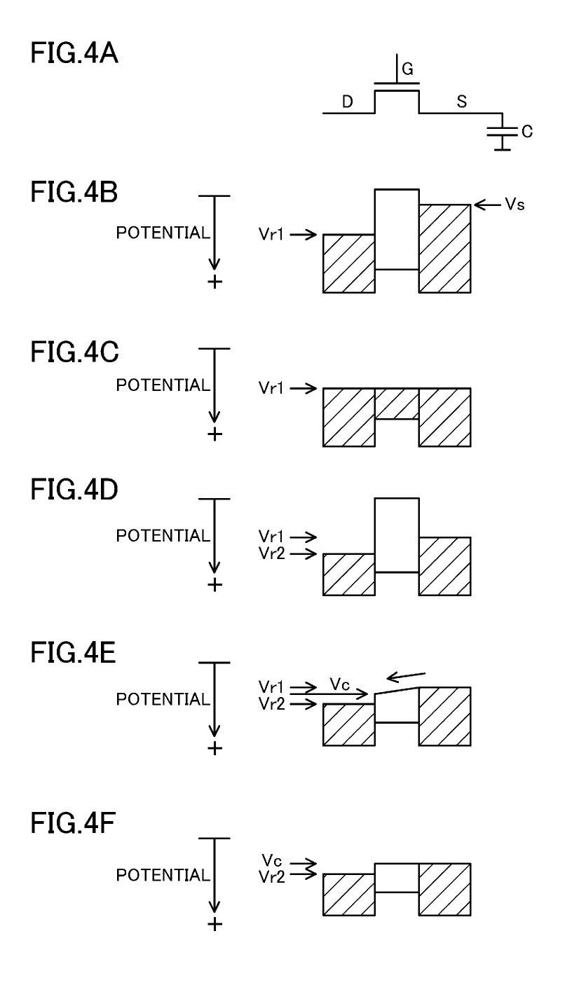

FIG. 4A illustrates a circuit configuration in the periphery of the reset transistor. FIGS. 4B-4F illustrate potentials at corresponding positions of the circuit of FIG. 4A in steps of the reset operation. In FIGS. 4B-4F, hatched areas indicate that electrons exist in the areas. As illustrated in FIG. 4A, the source S of the reset transistor is connected to a signal storage capacitor C.

First, as illustrated in FIG. 4B, a first reset voltage Vr1 is applied to the drain D of the reset transistor. The gate G of the reset transistor in this step is in an off state, and signal charge is stored in the signal storage capacitor, so that the signal storage capacitor has a signal voltage Vs. Next, as illustrated in FIG. 4C, the gate G of the reset transistor is turned on to reset the voltage of the source S to the first reset voltage Vr1. In this way, part of the signal charge is discharged to the drain D. The series of the operation described above is referred to as a hard reset.

After the hard reset, the gate G is brought back into the off state. Here, reset noise remains in the source S and the signal storage capacitor. This occurs because heat noise generated in a channel in turning on the gate G is fixed and remains when the gate G is turned off. The remaining noise has a value of √kTC in a charge region, and a value of √(kT/C) in a voltage region, where the capacitance value of the signal storage capacitor is C. Note that k is Boltzmann's constant, and T is the absolute temperature.

Next, as illustrated in FIG. 4D, a second reset voltage Vr2 is applied to the drain D. Subsequently, as illustrated in FIG. 4E, the gate G is turned on so that the channel potential Vc of the gate G is between the first reset voltage Vr1 and the second reset voltage Vr2, thereby discharging the signal charge remaining in the signal storage capacitor. Here, the channel of the gate G is in a weak-inversion state. The series of operation described above is referred to as a soft reset. After the soft reset, the potential of the source S has a value near the channel potential Vc. However, as illustrated in FIG. 4F, the potential of the source S gradually increases over time. Here, noise generated in the source S and the signal storage capacitor has a value of √(kTC/2) in the charge region, and a value of √(kT/2C) in the voltage region. Compared to the case where only a hard reset is performed, noise is reduced to √(½). When only the soft reset is performed without performing the hard reset, a phenomenon called capacitative image lag occurs. Thus, a combination of the hard reset and the soft reset is required.

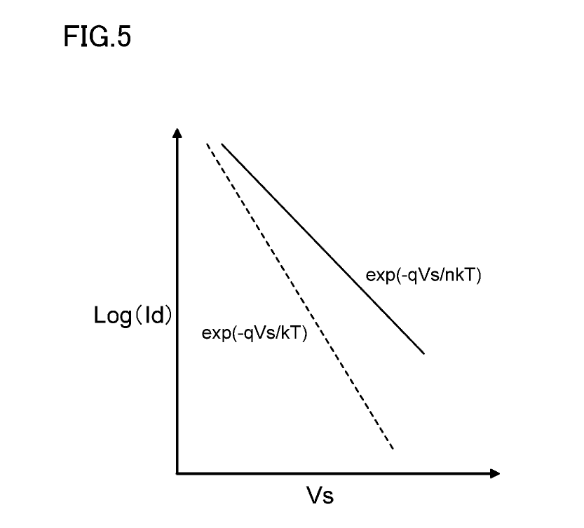

Reducing noise by the normal combination of the hard reset and the soft reset described above is effective when the gate length of a transistor is sufficiently large. However, when the gate length is reduced due to miniaturization of the transistor, the following problem arises. FIG. 5 illustrates the voltage-current characteristic in a weak-inversion region of the transistor. The horizontal axis indicates the source voltage Vs, and the vertical axis indicates the drain current Id.

As indicated by the broken line in FIG. 5, the drain current Id of a transistor having a sufficiently large gate length is proportional to (−qVs/kT) (q is the charge amount). The noise level of the soft reset in the case of using such a transistor is √(kTC/2) in the charge region, and is √(kT/2C) in the voltage region. In contrast, as illustrated by the solid line in FIG. 5, the drain current Id of a miniaturized transistor is (−qVs/nkT) (n is a positive number) due to the short channel effect. The noise of the soft reset here is √(nkTC/2) in the charge region, and is √(nkT/2C) in the voltage region. There are also cases where n exceeds 2, and in these cases, the noise of the soft reset is higher than that of the hard reset. When a weak-inversion current includes only a diffusion current, n is 1, but when the channel length is reduced, and a drift current increases, n approaches 2. When the channel potential starts being modulated by the source voltage due to the short channel effect, n further increases, and exceeds 2. As described above, in small-size pixels using miniaturized transistors, the noise-reduction effect by the soft reset cannot be expected.

The present embodiment performs the following operation to allow noise to be reduced even when miniaturized transistors are used in pixels.

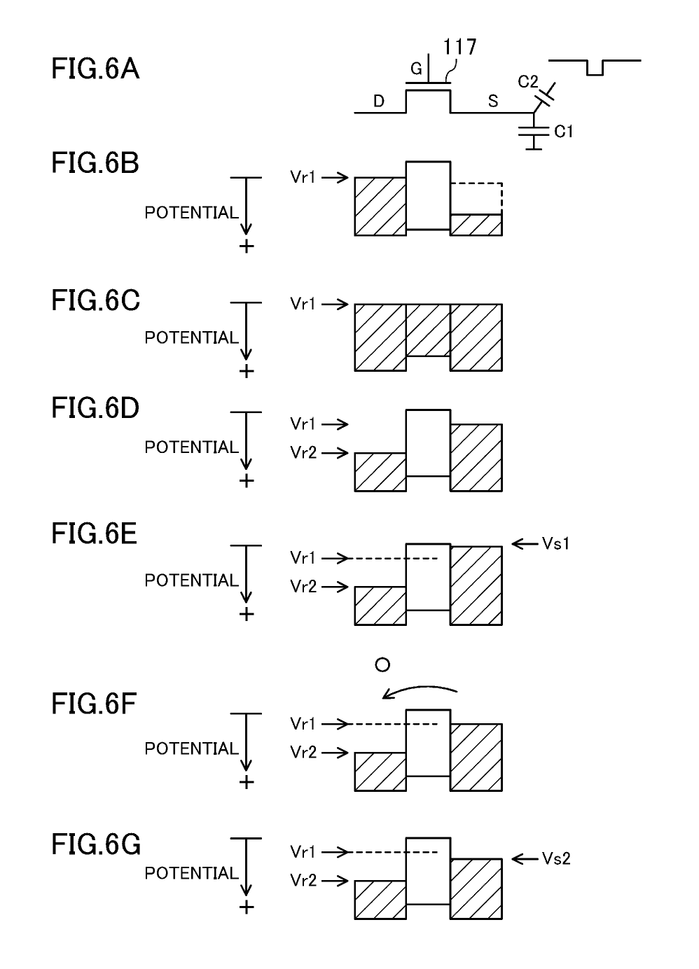

FIG. 6A illustrates a circuit configuration in the periphery of the reset transistor 117 of the present embodiment. FIGS. 6A-6G illustrate potentials at corresponding positions of the circuit in steps of reset operation. As illustrated in FIG. 6A, the solid-state image pickup device of the present embodiment includes a signal storage capacitor C1 and a reset control capacitor C2 which are connected to the source S of the reset transistor 117. It is preferable that the capacitance value of the reset control capacitor C2 be sufficiently smaller than the capacitance value of the signal storage capacitor C1. Moreover, the reset control capacitor C2 may use the photoelectric conversion film 45 between the pixel electrode 46 and the transparent electrode 47 as a capacitative element. Alternatively, a capacitative element may be separately formed.

First, as illustrated in FIG. 6B, a first reset voltage Vr1 is applied to the drain D of the reset transistor. In the reset operation of the present embodiment, Vr1 is 0 V, or has a value near 0 V. Here, a positive signal is stored in the signal storage capacitor C1.

Next, as illustrated in FIG. 6C, the gate G of the reset transistor is turned on to set the source S of the reset transistor to the vicinity of 0 V by the hard reset.

Next, as illustrated in FIG. 6D, the gate G is turned off, and a second reset voltage Vr2 is applied to the drain D.

Next, as illustrated in FIG. 6E, a negative pulse is applied to the reset control capacitor C2 to guide the potential of the source S toward a negative voltage Vs1. The potential of the source tends to return to 0 V as illustrated in FIG. 6F.

After termination of the negative pulse to the reset control capacitor C2, so that as illustrated in FIG. 6G, the source of the reset transistor is biased to a positive potential Vs2 which is slightly higher than 0 V. This state is referred to as a reset state in which storing signal charge is started.

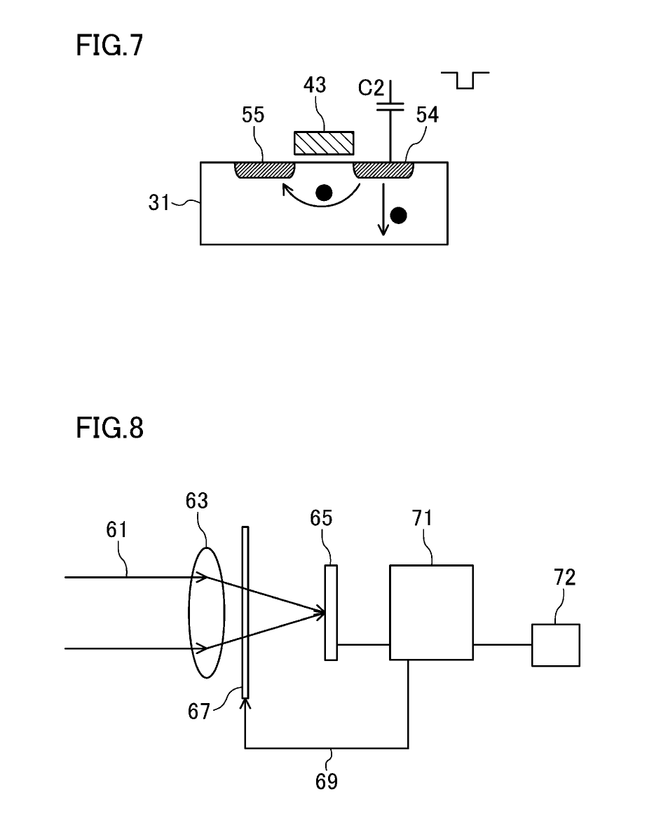

In FIG. 6F, the reason why the potential of the source S tends to return to 0 V can be described as follows. FIG. 7 illustrates a cross-sectional configuration of the reset transistor 117. In the present embodiment, the semiconductor substrate 31 is p type, and is in a forward bias state when the n-type diffusion layer 54 serving as the source has a negative voltage, and thus electrons of the source are released into the semiconductor substrate 31. No channel is formed below the gate electrode 43, and thus the electrons cannot pass below the gate electrode 43. Some of the released electrons recombine with holes in a deep portion of the semiconductor substrate 31, and the rest of the released electrons are transported to the diffusion layer 55 serving as the drain. Through the above-described mechanism, the potential of the source of the reset transistor tends to return to 0 V.

When the reset operation described in the present embodiment is performed, noise is substantially √(kTC/2) in the charge region, and is substantially √(kT/2C) in the voltage region, and thus, is reduced to 1/λ2 which is the noise level in the case of the hard reset. The operation of releasing electrons into the substrate is bipolar operation. Thus, holes which are majority carriers are collected around the released electrons which are minority carriers, so that electrical neutralization is locally achieved. Thus, the electrons flow by diffusion, and a phenomenon such as the short channel effect of the transistor does not occur.

Next, operation of the solid-state image pickup device of the present embodiment installed in an image pickup system using a mechanical shutter will be described. FIG. 8 illustrates a configuration of the image pickup system in which the solid-state image pickup device of the present embodiment is installed. As illustrated in FIG. 8, incident light 61 passes through a lens 63, and is concentrated on a solid-state image pickup device 65. A mechanical shutter 67 controls whether the incident light 61 is passed or shielded. Opening/closing the mechanical shutter is controlled by a signal applied to a mechanical shutter control line 69. An electrical signal converted in the solid-state image pickup device is processed in a signal processing chip 71, and is stored in a memory 72.

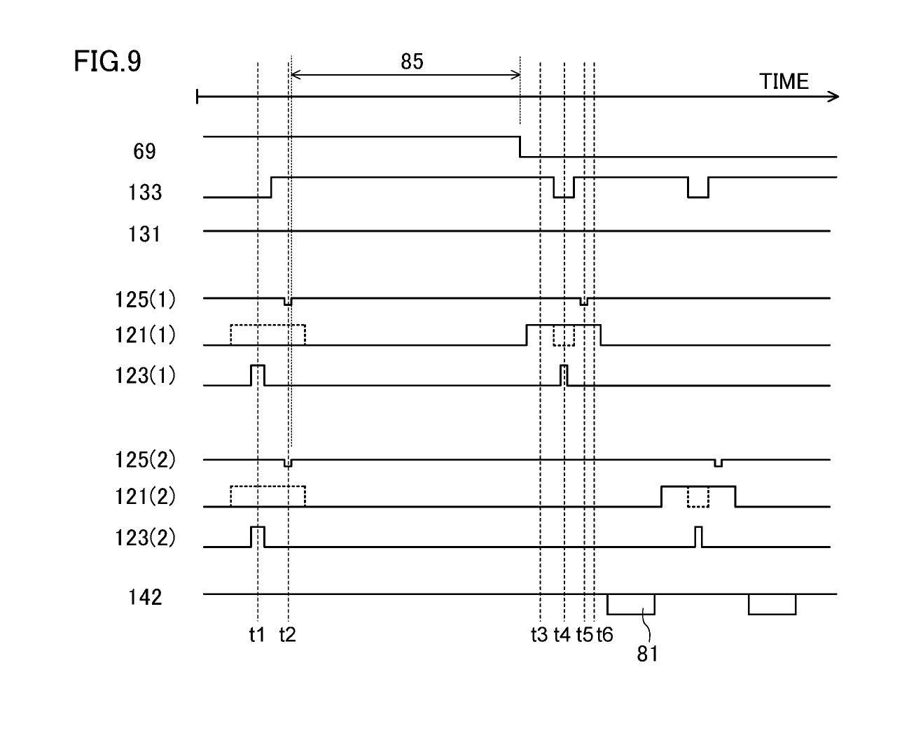

FIG. 9 illustrates operation timing of the image pickup system. In FIG. 9, when signal lines have to be distinguished from each other by means of rows or columns, indices indicating rows or columns are added. For example, reference number 121(n) denotes the address control line of the nth row.

First, the mechanical shutter control line 69 is at a high level, the mechanical shutter is in an open state, and the reset drain control line 133 is at a low level near 0 V. At timing t1, the reset control lines 123 of the rows are switched to the high level, and the reset transistors 117 are turned on, thereby resetting the gates of the amplifier transistors 113 to which the photoelectric converters 111 are connected. Next, the reset drain control line 133 is switched to the high level. Then, at timing t2, a small-amplitude pulse in the negative direction is applied to the bipolar operation control lines 125 to guide the sources of the reset transistors 117 toward a negative potential. In this way, electrons are released into the semiconductor substrate, thereby resetting all the pixels 11. Subsequently, the incident light is subjected to photoelectric conversion, and is stored, and the mechanical shutter control line 69 is switched to the low level to close the mechanical shutter. Then, the address control line 121(1) of the first row is switched to the high level, an output signal of the amplifier transistor 113 of the first row is read, and at timing t3, the signal is captured into the column signal processing section 21 illustrated in FIG. 1. Next, at timing t4, the reset drain control line 133 is switched to the low level, the reset control line 123(1) of the first row is switched to the high level, and the reset transistor 117 of the first row is turned on. In this way, the gate of the amplifier transistor 113 to which the photoelectric converter 111 is connected is reset. Next, the reset drain control line 133 is switched to the high level, and then at timing t5, a small-amplitude pulse in the negative direction is applied to the bipolar operation control line 125(1) of the first row to guide the source of the reset transistor 117 toward a negative potential. In this way, electrons are released into the semiconductor substrate to reset the pixel 11 of the first row. Next, at timing t6, an output of the amplifier transistor 113 of the first row is captured into the column signal processing section 21. Signal processing such as computing a difference with respect to the signal captured into the column signal processing section 21 at timing t3 is performed. Then, from the horizontal output 142, a signal 81 of the first row is read. Similar operation is repeated for the second and subsequent rows to sequentially read signals. In this way, a still-picture signal in the case of performing the global reset is read. A shutter time 85 in which the entirety of the incident light is converted to a signal is a period from the time at which the small-amplitude negative pulse applied to the bipolar operation control lines 125 rises to the time at which the mechanical shutter is closed.

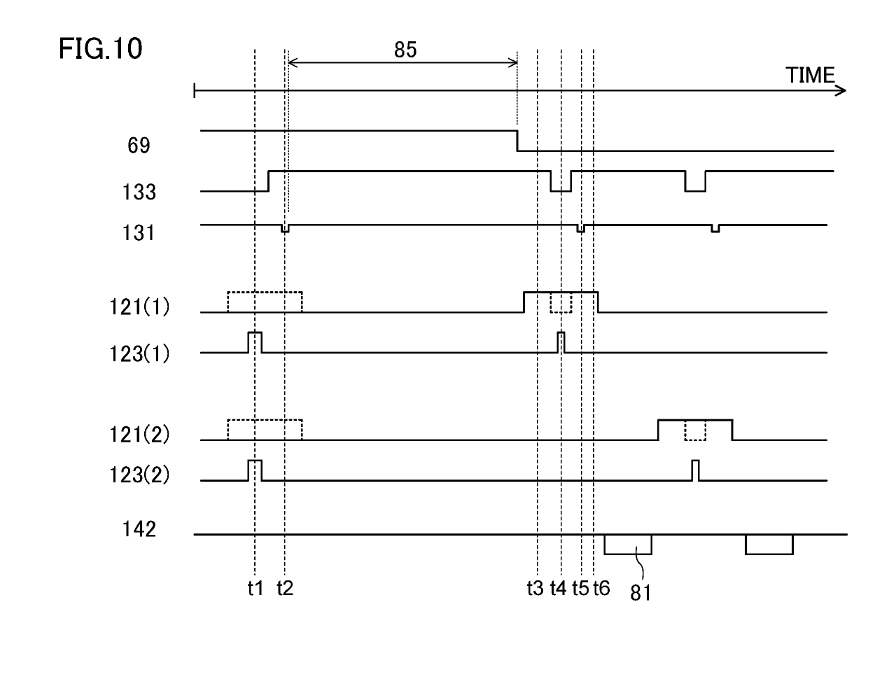

In FIG. 1, the configuration including the reset control capacitor 119 and the bipolar operation control line 125 is illustrated. However, instead of separately providing a reset control capacitative element, the capacitor of the photoelectric converter 111 may be used as a reset control capacitor. In this case, operation as illustrated in FIG. 10 may be performed. Instead of applying the small-amplitude pulse in the negative direction to the bipolar operation control lines, a similar small-amplitude pulse in the negative direction may be applied to the photoelectric converter control line 131 as illustrated in FIG. 10. The photoelectric converter control line 131 is not separated for each row, so that the pulse is applied to all the pixels at the same time. Note that the small-amplitude pulse in the negative direction which is applied to the photoelectric converter control line 131 does not mean a negative voltage pulse. A positive voltage is applied to the photoelectric converter control line 131, and a low-voltage pulse in the negative direction is applied.

### Variation of First Embodiment

In the first embodiment, a solid-state image pickup device for performing the global reset has been described. In recent years, taking moving images by using digital cameras has been requested, and there may be cases where not only the global reset but also the rolling reset is required.

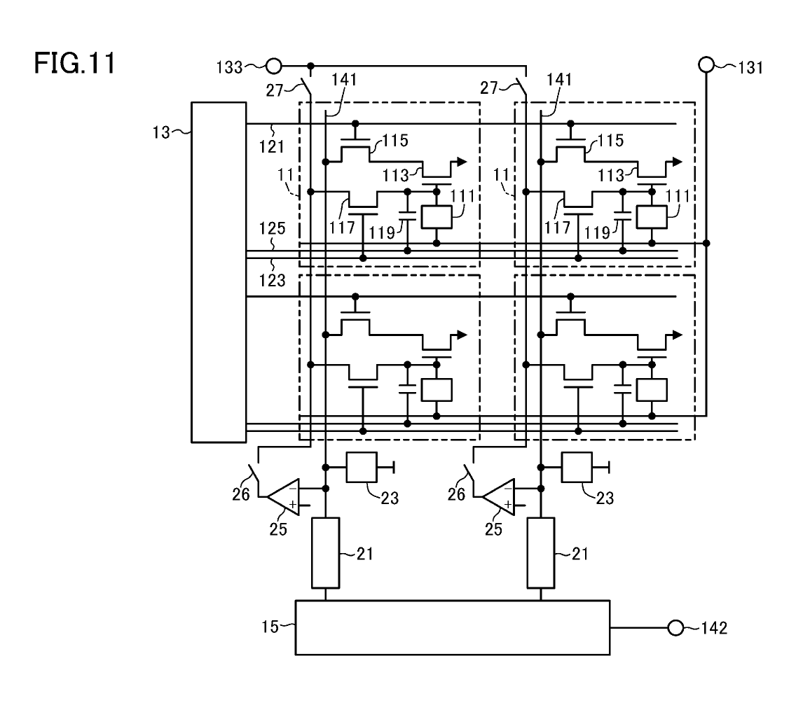

FIG. 11 illustrates a circuit configuration of a solid-state image pickup device capable of switching between the global reset and the rolling reset. In FIG. 11, the same reference numerals as those shown in FIG. 1 are used to represent equivalent elements, and the explanation thereof will be omitted.

As illustrated in FIG. 11, in the solid-state image pickup device of the present variation, a feedback unit by which a voltage output inverted with respect to an input of the amplifier transistor 113 is fed back to the drain of the reset transistor 117 is provided to each column. Specifically, a differential amplifier 25 whose negative input terminal is connected to the vertical signal line 141 is provided. An output of the differential amplifier 25 is connected via a feedback switch 26 to the reset drain control line 133. The reset drain control line can be separated by a reset drain connection switch 27 for each column. When the feedback switch 26 is turned off, and the reset drain connection switch 27 is turned on, the global reset can be performed by the same operation as that of the solid-state image pickup device of the first embodiment. In contrast, when the feedback switch 26 is turned on, and the reset drain connection switch 27 is turned off, noise reduction operation can be performed, and the rolling reset can be performed. The reset drain control line preferably operates near 0 V also in the rolling reset, and thus both positive power and negative power are preferably supplied to the differential amplifier 25. Note that instead of providing the feedback switch 26, the vertical signal line 141 may be connected to a power supply via a vertical signal line fixing switch. In this case, the vertical signal line fixing switch is turned on to fix the potential of the vertical signal line, so that it is possible to supply a constant voltage to the reset drain control line 133 via the differential amplifier 25.

### Second Embodiment

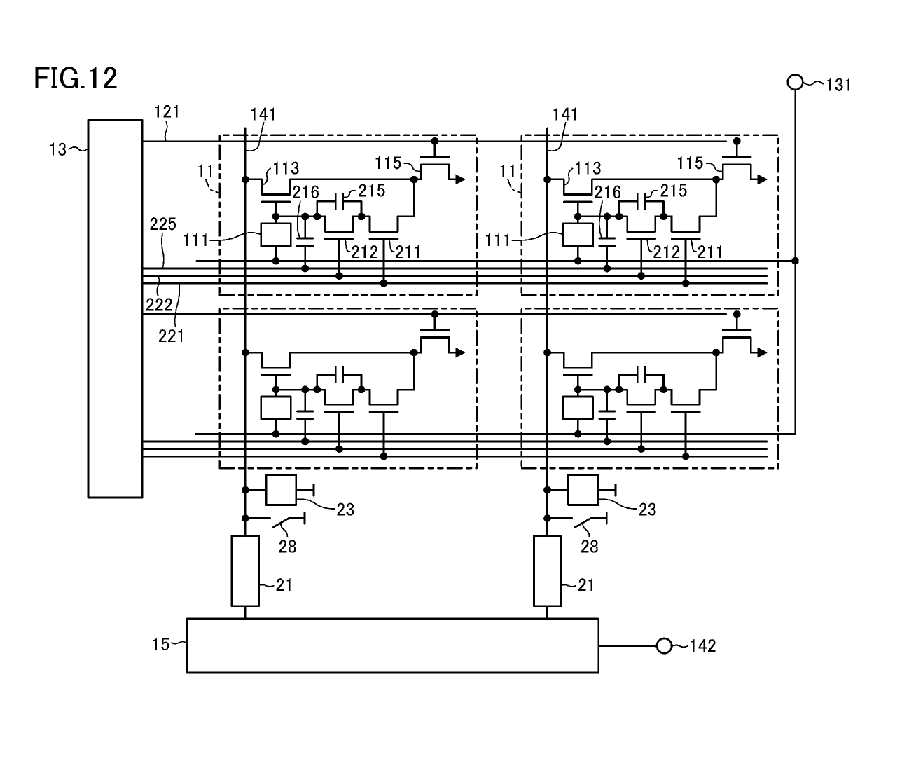

FIG. 12 illustrates a circuit configuration of a solid-state image pickup device according to a second embodiment. In FIG. 12, the same reference numerals as those shown in FIG. 1 are used to represent equivalent elements, and the explanation thereof will be omitted. In the solid-state image pickup device of the present embodiment, a first feedback transistor 211 and a second feedback transistor 212, instead of the reset transistor, are connected in series between the photoelectric converter 111 and the address transistor 115. Moreover, the source of the amplifier transistor 113 is connected to the vertical signal line 141, and the drain of the amplifier transistor 113 is connected to the source of the address transistor 115. The gate of the first feedback transistor 211 is connected to a first feedback control line 221, the source of the first feedback transistor 211 is connected to the drain of the second feedback transistor 212, and the drain of the first feedback transistor 211 is connected to the source of the address transistor 115. The gate of the second feedback transistor 212 is connected to a second feedback control line 222, and the source of the second feedback transistor 212 is connected to the photoelectric converter 111. Between the source and the drain of the second feedback transistor 212, a feedback capacitor 215 is connected. Between the source of the second feedback transistor 212 and a zero-bias control line 225, a zero-bias capacitor 216 is connected. Moreover, a vertical signal line fixing switch 28 is connected to the vertical signal line 141 to fix the voltage of the vertical signal line 141 at a constant voltage.

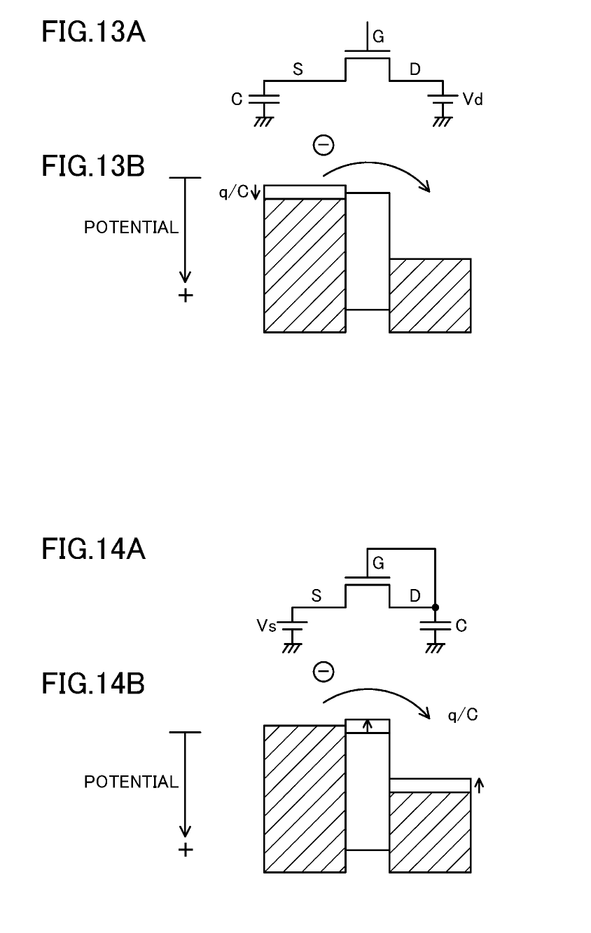

Next, an operation principle of the solid-state image pickup device of the present embodiment will be described with reference the drawings. FIG. 13A illustrates a transistor in which the source S is connected to a capacitor C, a bias voltage Vd is applied to the drain D, and the gate G has a fixed voltage. FIG. 13B illustrates potentials at the corresponding components. The source S is in a floating state, and thus when electrons flow to the drain D, the potential of the drain D gradually increases. When the potential of a channel formed below the gate G is at a comparable level with the potential of the source, a current flows due to thermal diffusion of electrons which is called a weak-inversion current. The noise level here is √(kTC/2) in the charge region. This is because one electron is released from the source, the potential of the source increases by q/C, so that the probability of electron being released next is reduced by (q²/kTC) fold.

FIG. 14A illustrates a transistor in which a bias voltage Vs is applied to the source S, and the drain D and the gate G are connected to a capacitor C. FIG. 14B illustrates potentials at corresponding components. In this case, when electrons flow from the source S to the drain D to reduce the potential of the drain D, the voltage of the gate G also decreases, so that electrons flowing from source S into the drain D are gradually reduced. When one electron is released, the probability of an electron being released next is reduced by (q²/kTC) fold, so that the noise level here is √(kTC/2).

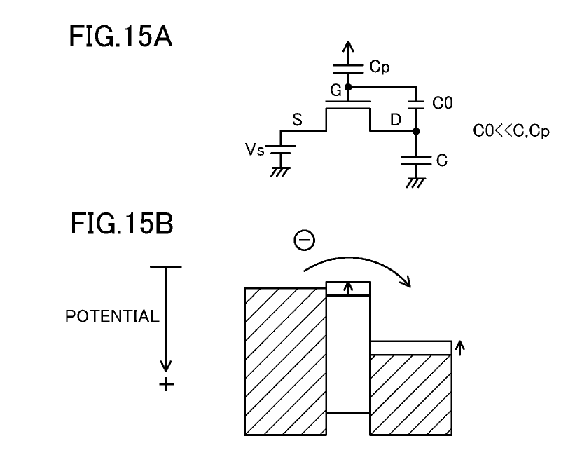

FIG. 15A illustrates a transistor in which a bias voltage Vs is applied to the source S, a capacitor Cp is connected to the gate G, the gate G and the drain D are connected to a capacitor C, and a small capacitor C0 is inserted between the drain D and the gate G. FIG. 15B illustrates potentials at the corresponding components. The capacitor Cp connected to the gate G may be, for example, the capacitance of the photoelectric conversion film. In the case where C0 is sufficiently smaller than C and than Cp, when one electron is released from the source S, the probability of an electron being released next is reduced by (q²/kTC·(C0/Cp)) fold. Thus, the noise level at the drain D is √(kTC·Cp/2C0), that is, increased. However, the noise level at the gate G is √(kTC·C0/2 Cp), that is, reduced. When C is substantially comparable to Cp, the noise level is √(kTC0/2), and is reduced to a lower level by the small capacitor C0.

As described above, when a feedback capacitor having a small capacitance value is used, noise can be reduced by conversion of capacity. However, due to the short channel effect of the transistor, the effect of reducing the noise may be reduced. A transistor used for feedback corresponds to the amplifier transistor of the pixel 11 as described later. Thus, when the gate length of the amplifier transistor is as large as possible, it is possible to reduce the short channel effect, and to effectively reduce the noise. The size of transistors other than the amplifier transistor is reduced as much as possible, and the gate length of the amplifier transistor may be increased.

Here, feedback will be briefly described. When an electron is released from the source into the drain, the voltage of the drain is reduced. The degree of reduction in voltage of the drain is higher, when the voltage of the gate is higher. Thus, with respect to the voltage of the gate, the voltage of the drain is an inverted voltage. The voltage of the drain which is inverted with respect to the voltage of the gate is fed back to the gate, so that negative feedback can be achieved.

In the solid-state image pickup device illustrated in FIG. 12, the vertical signal line fixing switch 28 is turned on to fix the voltage of the source of the amplifier transistor 113. In this state, the first feedback transistor 211 and the second feedback transistor 212 are turned on, the address transistor 115 is turned on, and then the address transistor 115 is brought back into an off state. Here, as illustrated in FIG. 14, a high level of noise due to a large capacitor connected to the gate and the drain remains in the gate and the drain. Next, the second feedback transistor 212 is turned off, the address transistor 115 is turned on, and then the address transistor 115 is brought back into the off state. In this way, as illustrated in FIG. 15, the noise remaining in the gate and the drain is reduced to √(kTC0/2) resulting from a sufficiently small feedback capacitor 215.

As described above, the feedback transistor also serves as a reset transistor for resetting signal charge. That is, the solid-state image pickup device of the present embodiment can be considered that each pixel includes a feedback unit for feeding a voltage obtained by inverting an input of an amplifier transistor back to a reset transistor.

When the operation described above is performed, the amplifier transistor 113 has to be enhancement type as illustrated in FIG. 12. Thus, the voltage of the diffusion layer connected to the photoelectric converter 111 is necessarily a positive voltage having a certain value, and cannot be near 0 V. For this reason, a zero-bias capacitor 216 is provided so that the voltage of the diffusion layer is set to a positive voltage in the feedback operation and in reading signals, and is set to a voltage near 0 V in storing the signals.

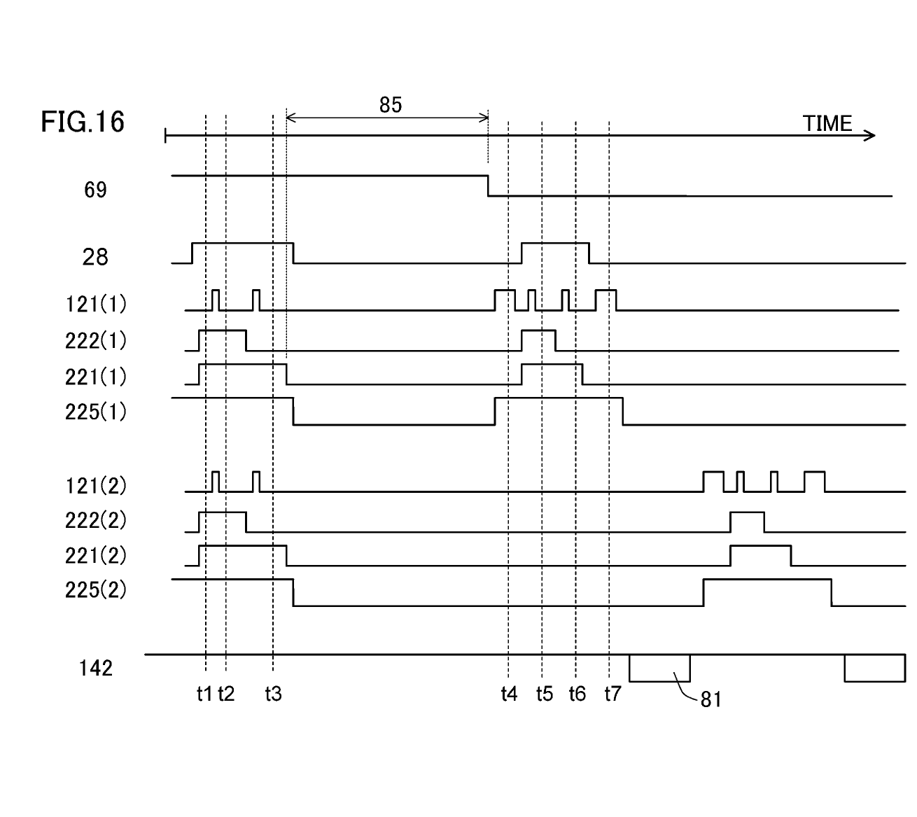

FIG. 16 illustrates operation timing of the solid-state image pickup device of the present embodiment. First, the mechanical shutter control line 69 is at a high level, the shutter is in an open state, the vertical signal line fixing switch 28 is in the on state, and the zero-bias control lines 225 are at the high level. At timing t1, the first feedback control lines 221 and the second feedback control lines 222 are switched to the high level so that the first feedback transistors 211 and the second feedback transistor 212 of all the pixels 11 are turned on. Subsequently, the address control lines 121 are turned on, and then at timing t2, the address control lines 121 are brought back into the off state to perform first feedback. Next, the second feedback control lines 222 are switched to a low level. After that, the address control lines 121 are turned on, and then at timing t3, the address control lines 121 are brought back into the off state to perform second feedback. Next, the first feedback control lines 221 are switched to the low level to end the feedback operation. The series of operation can achieve a reset state in which noise is reduced, and storing signals is started at the timing at which the first feedback control lines 221 are switched to the low level. During a signal storing period, the zero-bias control lines 225 are at the low level, and the voltage of a signal storing section is reduced.

Next, the mechanical shutter control line 69 is switched to the low level to close the mechanical shutter. Then, the zero-bias control line 225(1) of the first row and the address control line 121(1) of the first row are switched to the high level to capture an output signal from the amplifier transistor 113 of the first row into the column signal processing section 21 at timing t4. Next, the vertical signal line fixing switch 28 is turned on. Moreover, on the first row, the first feedback operation is performed at timing t5, and the second feedback operation is performed at timing t6. Next, the address control line 121(1) of the first row is switched to the high level to capture an output of the amplifier transistor 113 of the first row into the column signal processing section 21 at timing t7. Signal processing such as computing a difference with respect to the signal captured at timing t4 is performed, and then a signal 81 of the first row is read from the horizontal signal read section 15. Similar operation is repeated for the second and subsequent rows to read signals. In this way, a still-picture signal in the case where the global reset is performed is read. A shutter time 85 which is the signal storing time is a period from the timing at which the first feedback control lines 221 are switched to the low level to the timing at which the mechanical shutter is closed.

### Variation of Second Embodiment

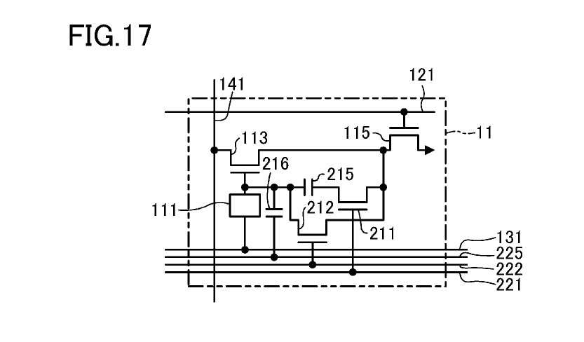

FIG. 17 illustrates a circuit configuration of a pixel 11 of a solid-state image pickup device according to a variation of the second embodiment. As illustrated in FIG. 17, in the solid-state image pickup device of the present variation, the drain of the second feedback transistor 212 is connected to the drain of the amplifier transistor 113, and the feedback capacitor 215 is connected between the source of the second feedback transistor 212 and the source of the first feedback transistor 211. With this configuration, operation similar to that of the solid-state image pickup device of the second embodiment can also be performed.

### Third Embodiment

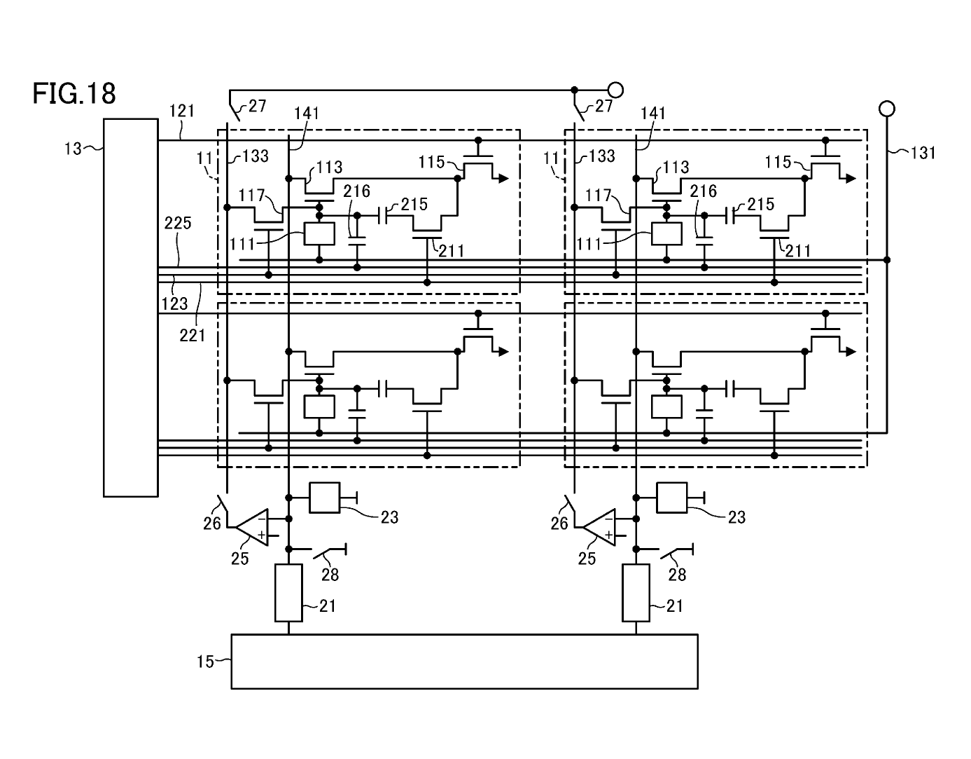

FIG. 18 illustrates a circuit configuration of a solid-state image pickup device according to a third embodiment. In FIG. 18, the same reference numerals as those shown in FIG. 12 are used to represent equivalent elements, and the explanation thereof will be omitted. In the solid-state image pickup device of the present embodiment, a configuration allowing the rolling reset operation described in the variation of the first embodiment is added to a solid-state image pickup device configured to reduce noise by using the zero-bias capacitor described in the second embodiment and the variation of the second embodiment. Thus, a feedback unit by which a voltage output inverted with respect to an input of an amplifier transistor 113 is fed back to the drain of a reset transistor 117 is provided to each column. Specifically, the reset transistor 117 is connected between the gate of the amplifier transistor 113 and a reset drain control line 133, and the gate of the reset transistor 117 is connected to a reset control line 123. An output terminal of a differential amplifier 25 whose negative input terminal is connected to a vertical signal line 141 is connected to the reset drain control line 133 via a feedback switch 26. The reset drain control line can be separated for each column by a reset drain connection switch 27. A vertical signal line fixing switch 28 for fixing the voltage of the vertical signal line 141 at a constant voltage is connected to the vertical signal line 141. The reset transistor 117 is provided, so that the second feedback transistor is no longer necessary.

When the global reset operation is performed, the reset drain connection switches 27 are turned on, and the feedback switches 26 are turned off. In this state, all the pixels 11 are reset by the reset transistors 117. Then, the vertical signal line fixing switches 28 are turned on, and the feedback operation is performed by using first feedback transistors 211 in the same manner as in the second embodiment and the variation of the second embodiment to reduce noise. Note that when the reset drain control lines 133 are operated near 0 V, the zero-bias capacitors 216 are not necessary.

When the rolling reset is performed, the feedback switch 26 is turned on, and the reset drain connection switch 27 and the vertical signal line fixing switch 28 are turned off. An address transistor 115 is inserted between the amplifier transistor 113 and a power supply line, but can be operated in the same manner as in the case where the address transistor 115 is inserted between the vertical signal line 141 and the amplifier transistor 113.

The solid-state image pickup devices according to the embodiments and the variations can reduce noise generated in resetting signal charge in stacked solid-state image pickup devices. Moreover, the global reset can be performed without feeding a large current.

Moreover, each embodiment has described an example of a so-called one-pixel cell structure in which a photoelectric conversion element, a transfer transistor, a floating diffusion, a reset transistor, and an amplifier transistor are provided to each pixel. However, it may be possible to use a so-called multiple-pixel cell structure in which a plurality of photoelectric conversion elements are included in a pixel, and further any one or all of a floating diffusion, a reset transistor, and an amplifier transistor are shared among pixels.

The solid-state image pickup device according to the present disclosure can provide a stacked solid-state image pickup device which is capable of performing a global reset, and has reduced noise, and a reduced dark current, and thus is useful, in particular, as a small-size image pickup device, and the like.

What is claimed is:

1. A solid-state image pickup device comprising:
a semiconductor substrate;
a plurality of pixels arranged in rows and columns on the semiconductor substrate; and
a vertical signal line provided to each column, wherein
each pixel includes a reset transistor, an address transistor, an amplifier transistor, and a photoelectric converter which are formed on the semiconductor substrate,
the photoelectric converter includes a photoelectric conversion film formed over the semiconductor substrate, a pixel electrode formed on a surface of the photoelectric conversion film facing the substrate, and a transparent electrode formed on a surface of the photoelectric conversion film opposite to the pixel electrode,
a gate of the amplifier transistor is connected to the pixel electrode,
a source of the reset transistor is connected to the pixel electrode, and
the solid-state image pickup device performs
hard reset operation in which a first reset voltage is applied to a drain of the reset transistor, and then the reset transistor is turned on, and
soft reset operation in which a second reset voltage at a higher level than the first reset voltage is applied to the drain of the reset transistor, and then a pulse in a negative direction is applied to the source of the reset transistor via a capacitor.

2. The solid-state image pickup device of claim 1, wherein
the first reset voltage is 0 V or a positive voltage near 0 V, and
the soft reset operation is performed after the reset transistor is turned off.

3. The solid-state image pickup device of claim 1, wherein
the capacitor is formed by using the photoelectric conversion film as a capacitor film.

4. The solid-state image pickup device of claim 1, further comprising:
a reset drain control line provided to each column and connected to the drains of the reset transistors; and
differential amplifiers each having input terminals one of which is connected to the reset drain control line and an output terminal connected to the reset drain control line via a switch.

5. A solid-state image pickup device comprising:
a semiconductor substrate;
a plurality of pixels arranged in rows and columns on the semiconductor substrate;
a vertical signal line provided to each column; and
vertical signal line fixing switches each configured to fix a potential of the vertical signal line, wherein
each pixel includes a first feedback transistor, a second feedback transistor, an address transistor, an amplifier transistor, a photoelectric converter, a feedback capacitor, and a zero-bias capacitor which are formed on the semiconductor substrate,
the photoelectric converter includes a photoelectric conversion film formed over the semiconductor substrate, a pixel electrode formed on a surface of the photoelectric conversion film facing the substrate, and a transparent electrode formed on a surface of the photoelectric conversion film opposite to the pixel electrode,
the amplifier transistor has a gate connected to the pixel electrode, a source connected to the vertical signal line, and a drain connected to a source of the address transistor,
the second feedback transistor has a source connected to the pixel electrode, and a drain connected to a source of the first feedback transistor,
the first feedback transistor has a drain connected to the source of the address transistor,
the zero-bias capacitor is connected to the gate of the amplifier transistor, and
the feedback capacitor is connected between the source and the drain of the second feedback transistor.

6. The solid-state image pickup device of claim 5, wherein
the solid-state image pickup device performs:
first feedback operation in which
the vertical signal line fixing switch is turned on to fix a voltage of the vertical signal line,
a high-level voltage is applied to the zero-bias capacitor,
the first feedback transistor and the second feedback transistor are turned on, and
the address transistor is turned on, and then the address transistor is brought back into an off state;
second feedback operation in which
the vertical signal line fixing switch is turned on to fix the voltage of the vertical signal line,
the high-level voltage is applied to the zero-bias capacitor,
the first feedback transistor is turned on,
the second feedback transistor is turned off, and
the address transistor is turned on, and then the address transistor is brought back into the off state; and
storage operation in which
a low-level voltage is applied to the zero-bias capacitor, and
the first feedback transistor and the second feedback transistor are turned off.

7. The solid-state image pickup device of claim 5, wherein
a gate length of the amplifier transistor is greater than a gate length of each of the first feedback transistor, the second feedback transistor, and the address transistor.

8. A solid-state image pickup device comprising:
a semiconductor substrate;
a plurality of pixels arranged in rows and columns on the semiconductor substrate;
a vertical signal line provided to each column; and
vertical signal line fixing switches each configured to fix a potential of the vertical signal line, wherein
each pixel includes a first feedback transistor, a second feedback transistor, an address transistor, an amplifier transistor, a photoelectric converter, a feedback capacitor, a zero-bias capacitor which are formed on the semiconductor substrate,
the photoelectric converter includes a photoelectric conversion film formed over the semiconductor substrate, a pixel electrode formed on a surface of the photoelectric conversion film facing the substrate, and a transparent electrode formed on a surface of the photoelectric conversion film opposite to the pixel electrode,
the amplifier transistor has a gate connected to the pixel electrode, a source connected to the vertical signal line, and a drain connected to a source of the address transistor,
the second feedback transistor has a source connected to the pixel electrode, and a drain connected to the source of the address transistor,
the first feedback transistor has a source connected to the pixel electrode via the feedback capacitor, and a drain connected to the source of the address transistor, and
the zero-bias capacitor is connected to the gate of the amplifier transistor.

9. The solid-state image pickup device of claim 8, wherein
the solid-state image pickup device performs:
first feedback operation in which
the vertical signal line fixing switch is turned on to fix a voltage of the vertical signal line,
a high-level voltage is applied to the zero-bias capacitor,
the first feedback transistor and the second feedback transistor are turned on, and
the address transistor is turned on, and then the address transistor is brought back into an off state;
second feedback operation in which
the vertical signal line fixing switch is turned on to fix the voltage of the vertical signal line,
the high-level voltage is applied to the zero-bias capacitor,
the first feedback transistor is turned on,
the second feedback transistor is turned off, and
the address transistor is turned on, and then the address transistor is brought back into the off state; and
storage operation in which
a low-level voltage is applied to the zero-bias capacitor, and
the first feedback transistor and the second feedback transistor are turned off.

10. The solid-state image pickup device of claim 8, wherein
a gate length of the amplifier transistor is greater than a gate length of each of the first feedback transistor, the second feedback transistor, and the address transistor.

11. A solid-state image pickup device comprising:
a semiconductor substrate;
a plurality of pixels arranged in rows and columns on the semiconductor substrate;
a vertical signal line provided to each column;
a reset drain control line provided to each column;
vertical signal line fixing switches each configured to fix a potential of the vertical signal line; and
differential amplifiers each having input terminals one of which is connected to the vertical signal line and an output terminal connected to the reset drain control line via a switch, wherein
each pixel includes a feedback transistor, a reset transistor, an address transistor, an amplifier transistor, a photoelectric converter, a feedback capacitor, and a zero-bias capacitor which are formed on the semiconductor substrate,
the photoelectric converter includes a photoelectric conversion film formed over the semiconductor substrate, a pixel electrode formed on a surface of the photoelectric conversion film facing the substrate, and a transparent electrode formed on a surface of the photoelectric conversion film opposite to the pixel electrode,
the amplifier transistor has a gate connected to the pixel electrode, a source connected to the vertical signal line, and a drain connected to a source of the address transistor,
the feedback transistor has a source connected to the pixel electrode via the feedback capacitor, and a drain connected to the source of the address transistor,
the reset transistor has a source connected to the pixel electrode, and a drain connected to the reset drain control line, and
the zero-bias capacitor is connected to the gate of the amplifier transistor.

12. The solid-state image pickup device of claim 11, wherein
the solid-state image pickup device performs:
reset operation in which
a reset voltage is applied to the reset drain control line to bring the reset transistor into an on state;
feedback operation in which
the vertical signal line fixing switch is turned on to fix a voltage of the vertical signal line,
a high-level voltage is applied to the zero-bias capacitor,
the feedback transistor is turned on, and
the address transistor is turned on, and then the address transistor is brought back into an off state; and
storage operation in which
a low-level voltage is applied to the zero-bias capacitor, and
the feedback transistor is turned off.

13. The solid-state image pickup device of claim 11, wherein
a gate length of the amplifier transistor is greater than a gate length of each of the feedback transistor, the reset transistor, and the address transistor.

14. A solid-state image pickup device comprising:
a semiconductor substrate;
a plurality of pixels arranged in rows and columns on the semiconductor substrate;
a vertical signal line provided to each column; and
feedback units, wherein
each pixel includes a reset transistor having a function of resetting a signal charge, an address transistor, an amplifier transistor, and a photoelectric converter which are formed on the semiconductor substrate,
the photoelectric converter includes a photoelectric conversion film formed over the semiconductor substrate, a pixel electrode formed on a surface of the photoelectric conversion film facing the substrate, and a transparent electrode formed on a surface of the photoelectric conversion film opposite to the pixel electrode,
the amplifier transistor has a gate connected to the pixel electrode,
the reset transistor has a source connected to the pixel electrode,
each feedback unit is connected to a drain of the reset transistor and is configured to feed back a voltage output inverted with respect to an input of the amplifier transistor.

15. The solid-state image pickup device of claim 14, wherein
each feedback unit is provided to an associated one of the pixels.

16. The solid-state image pickup device of claim 14, wherein
each feedback unit is provided to an associated one of the columns in correspondence with the vertical signal line.

17. The solid-state image pickup device of claim 14, wherein
an input of the amplifier transistor in operation of the feedback unit is a positive voltage near 0 V at a direct current level.

18. The solid-state image pickup device of claim 16, further comprising:
a zero-bias capacitor capacitively coupled to the pixel electrode.

19. The solid-state image pickup device of claim 1, wherein
the solid-state image pickup device further has a function of switching between a global reset and a rolling reset.

20. A camera system comprising:
the solid-state image pickup device of claim 19.
